(19) United States
(12) Patent Application Publication
(10) Pub. No.: US 2007/0023614 A1
(43) Pub. Date: Feb. 1, 2007

(54) CMOS IMAGE SENSOR HAVING DARK CURRENT COMPENSATION FUNCTION

(75) Inventors: Deuk Hee PARK, SEOUL (KR); Won Tae CHOI, KYUNGKI-DO (KR); Shin Jae KANG, KYUNGKI-DO (KR); Joo Yul KO, KYUNGKI-DO (KR)

Correspondence Address: LOWE HAUPTMAN BERNER, LLP, 1700 DIAGONAL ROAD, SUITE 300, ALEXANDRIA, VA, 22314, US

(73) Assignee: SAMSUNG ELECTRO-MECHANICS CO., LTD., KYUNGKI-DO (KR)

(21) Appl. No.: 11/458,034

(22) Filed: Jul. 17, 2006

(30) Foreign Application Priority Data
Aug. 1, 2005 (KR) 10-2005-70336

(51) Int. Cl. H01L 31/00

(52) U.S. Cl. 250/214.1

(57) ABSTRACT

A CMOS image sensor has a function to compensate a photodetector pixel from a dark current by using a dark pixel. In the CMOS image sensor, the photodetector pixel includes a first reset transistor with a drain connected to a supply voltage and a photodetector diode connected between a source of the first reset transistor and a ground. The dark pixel includes a mirror transistor with a drain connected to the supply voltage and a gate and source connected to a gate of the first reset transistor and a dark photodiode shielded from external light. The dark photodiode is connected between the source of the mirror diode and the ground. The dark pixel provides a current having a magnitude equal with that of a dark current flowing through the dark photodiode to the photodetector diode. This delays the saturation rate of the CMOS image sensor pixel and enhances the dynamic range thereof.

### CLAIM OF PRIORITY

This application claims the benefit of Korean Patent Application No. 2005-70336 filed on Aug. 1, 2005, in the Korean Intellectual Property Office, the disclosure of which is incorporated herein by reference

### BACKGROUND OF THE INVENTION

1. Field of the Invention

The present invention relates to a Complementary Metal Oxide Semiconductor (CMOS) image sensor, and more particularly, a CMOS image sensor having a dark current compensation function in which a dark pixel having a dark photodiode shielded from external light is connected to at least one CMOS image sensor pixel to provide a current with the magnitude the same as that of a dark current occurring in the dark photodiode to a photodiode of the CMOS image sensor pixel in order to compensate the photodetector diode from a dark current, delay the saturation rate of the CMOS image sensor pixel, and enhance the dynamic range thereof.

2. Description of the Related Art

In general, each part of objects present in the natural world differs in brightness and wavelengths of light. An image sensor is a device that converts different brightness and wavelengths of the subjects into an electrical value of a signal processable level, using photo-reactive properties of semiconductors.

Typically, the image sensor is used at a per-pixel level. A plurality of image sensors are aligned on a line of certain standard to produce a pixel array. Then images of a certain standard are picked up via the pixel array.

The aforesaid image sensor includes a photo-reactive semiconductor device and a plurality of transistors for outputting an electrical change of the semiconductor device as an electrical signal of a certain level.

FIG. 1 is a circuit diagram illustrating a unit pixel of a general CMOS image sensor according to the prior art. Referring to FIG. 1, the CMOS image sensor includes a photo diode PD for changing a capacity value in response to light, a reset transistor Q1 for resetting the photo diode PD to detect a next signal, a drive transistor Q2 for acting as a source follower via an electrical signal stored in the photo diode PD and a select transistor Q3 for selecting an output of a detected value.

That is, if the reset transistor Q1 stays on for a predetermined duration in response to a reset signal Rx, charges remaining in the photo diode PD are released and the photo diode PD is emptied so that current is stored in the photo diode PD at an amount proportionate to the capacity value corresponding to light. In addition, the transistor Q2 amplifies a voltage of the photo diode PD into the electrical signal (output voltage) within a set range to output. The output voltage from the drive transistor Q2 is outputted in the addressing order of a pixel array if the select transistor Q3 is turned on.

In this conventional CMOS image sensor, the photo diode PD, even though not exposed to light at all, generates a dark current which is a leakage current. That is, the dark current causes the drive transistor Q2 to generate the output voltage, even if not receiving light at all.

Such a dark current is supplied to the drive transistor Q2, thereby shortening a saturation time of the driver transistor Q2. In a further explanation, the dark current is combined with current generated when the photo diode PD receives light, thereby shortening a saturation time. Disadvantageously, the dark current generated in the photo diode PD reduces a driving range of the CMOS image sensor.

Especially, the dark current, which is considerably sensitive to temperature, substantially doubles or more with 10° C. increase in its ambient temperature. As a result, the dark current further reduces a driving range of the CMOS image sensor.

In a conventional method to overcome the dark current-induced problem, an average value of the dark current generated in a dark pixel was calculated to compensate for an output of a non-dark pixel. However, according to such a conventional technology, the dark current generated in each pixel is not decreased but subtraction is processed externally based on a formula so that the unit pixel, if saturated, is inevitably degraded.

### SUMMARY OF THE INVENTION

The present invention has been made to solve the foregoing problems of the prior art and therefore an object according to certain embodiments of the present invention is to provide a CMOS image sensor having a dark current compensation function in which a dark pixel having a dark photodiode shielded from external light is connected to at least one CMOS image sensor pixel to provide a current with the magnitude the same as that of a dark current occurring in the dark photodiode to a photodiode of the CMOS image sensor pixel in order to compensate the photodetector diode from a dark current, delay the saturation rate of the CMOS image sensor pixel, and enhance the dynamic range thereof.

According to an aspect of the invention for realizing the object, there is provided a CMOS image sensor comprising: at least one photodetector pixel including a first reset transistor with a drain connected to a supply voltage and a photodetector diode connected between a source of the first reset transistor and a ground; and at least one dark pixel including a mirror transistor with a drain connected to the supply voltage and a gate and source connected to a gate of the first reset transistor and a dark photodiode shielded from external light, the dark photodiode connected between the source of the mirror diode and the ground, whereby a current having a magnitude equal with that of a dark current flowing through the dark photodiode is provided to the photodetector diode.

Preferably, the dark pixel further includes a second reset transistor with a drain connected to the source of the mirror transistor and a source connected to the ground, the second reset transistor receiving a reset signal through the gate.

Preferably, each of the first reset transistor and the mirror transistor comprises a p-channel Metal Oxide Semiconductor Field Effect Transistor (MOSFET).

According to an embodiment of the invention, the CMOS image sensor may comprise a plurality of the photodetector pixel arranged around and connected to a single one of the dark pixel to form a pixel group, in which the photodetector pixels preferably include a red-light photodetector pixel, a blue-light photodetector pixel and green light photodetector pixels at a ratio of 1:1:2.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a circuit diagram illustrating a unit pixel of a typical CMOS image sensor;

FIG. 2 is a circuit diagram illustrating a CMOS image sensor according to an embodiment of the invention;

FIG. 3 is a circuit diagram illustrating a CMS image sensor according to another embodiment of the invention; and

FIG. 4 is a diagram illustrating pixel arrangements of a CMOS image according to different embodiments of the invention.

### DETAILED DESCRIPTION OF THE PREFERRED EMBODIMENT

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout. Herein, a pixel for receiving and detecting light will be referred to as “photodetector pixel” and a diode for receiving and detecting light will be referred to as “photodiode.” In addition, a pixel and a diode which do not receive or detect light will be referred to as “dark pixel” and “dark diode,” respectively.

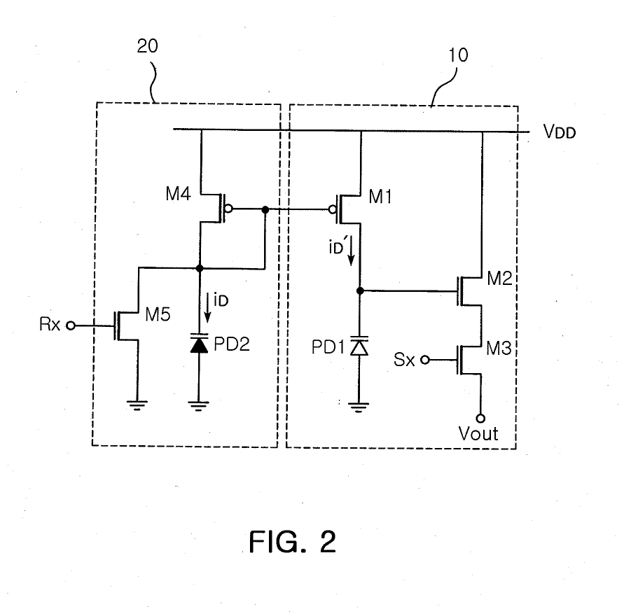

FIG. 2 is a circuit diagram illustrating a CMOS image sensor according to an embodiment of the invention. As shown in FIG. 2, the CMOS image sensor according to this embodiment includes a photopixel 10 for detecting a light and a dark pixel 20 connected to the photopixel 10 to compensate for a dark current of a photodetector diode PD1 in the photopixel 10.

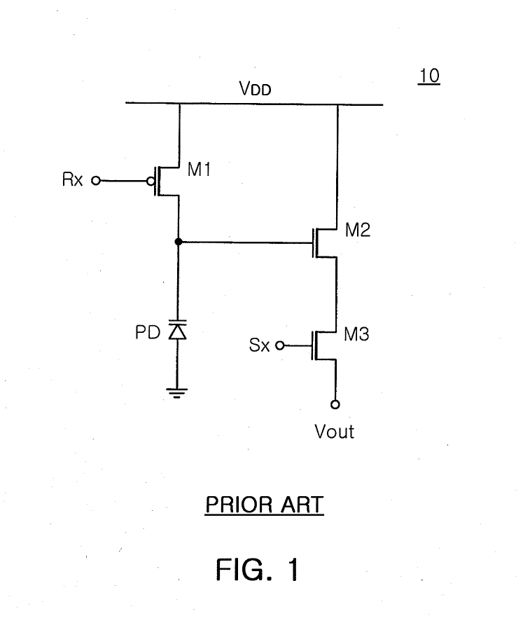

In this embodiment, the photopixel 10 may have substantially the same configuration as a unit pixel of a typical CMOS image sensor as shown in FIG. 1. That is, as shown in FIG. 2, the photopixel 10 includes a first reset transistor M1 having a drain connected to a supply voltage V_{DD}, the photodetector diode PD1 connected between a source of the first reset transistor M1 and a ground, a drive transistor M2 functioning as a source follower in response to an electric signal stored in the photodetector diode PD1 and a select transistor M3 for selecting the output of a detection value.

In this embodiment, the dark pixel 20 includes a mirror transistor M4 and a dark photodiode PD2. The mirror transistor M4 has a drain connected to the supply voltage V_{DD} and a gate and source connected to a gate of the first reset transistor M1. The dark photodiode PD2 is connected between the source of the mirror transistor M4 and the ground, and shielded from external light. The dark pixel 20 also includes a second reset transistor M5 having drain connected to the source of the mirror transistor M4, a source connected to the ground and a gate for receiving a reset signal Rx.

The mirror transistor M4 is connected by the drain to the supply voltage V_{DD}, and by the gate and the source to the gate of the first reset transistor M1 of the photopixel 10. In such a connection structure, the mirror transistor M4 and the first reset transistor M1, if made of a p-channel MOSFET, form a current mirror circuit. That is, a current flows through the source of the first reset transistor M1 with a magnitude the same as that flowing through the source of the mirror transistor M4.

With this mirror structure, as a current flows through the source of the mirror transistor M4 with a magnitude the same as that of a dark current, such a current with a magnitude the same as that of the dark current flows also through the source of the first reset transistor M1. This as a result can provide a current for compensating for the dark current to the photodetector diode PD1.

In order for the current with a magnitude the same as that of the dark current to flow through the source of the mirror transistor M4, the dark photodiode PD2 having a polarity the same as that of the photodetector diode PD1 is connected between the source of the mirror transistor M4 and the ground. The dark photodiode PD2 is a diode having the same characteristics as the photodetector diode PD1. Since the dark photodiode PD2 is shielded from external light, a dark current iD flows through it constantly.

Accordingly, the dark photodiode PD2 makes the dark current iD flow constantly through the source of the mirror transistor PD2. With the afore-said current mirror structure, a current iD′ with a magnitude the same as such dark current iD flows through the source of the reset transistor M1 of the photopixel 10, thereby providing the photodetector diode with a compensating current that has a magnitude corresponding to that of the dark current of the photodetector diode PD1. By providing the compensating current to the photodetector diode PD1, it is possible to delay the saturation rate of the photopixel 10 as well as to enhance the dynamic range thereof.

Now the operation of the CMOS image sensor of this embodiment will be described with reference to FIG. 2.

First, when a high level signal is inputted to the gate of the second reset transistor M5 for a predetermined time period, the second reset transistor M5 is turned on, and the gates of the mirror transistor M4 and the first reset transistor M1 become low level. Then, the mirror transistor M4 and the first reset transistor M1 are turned on. Thereby the photodetector diode PD1 in the photopixel 10 and the dark photodiode PD2 in the dark pixel 20 are reset to a reference voltage level.

Next, as the photodetector diode PD1 begins to detect light, the dark photodiode in the dark pixel 20 generates a dark current iD continuously since it is shielded from light constantly. Owing to the current mirror structure formed by the mirror transistor M4 and the first reset transistor M1, a current iD′ with a magnitude the same as the dark current iD flows through the source of the reset transistor M1 of the photodetector pixel 10, thereby providing the photodetector diode PD1 with a compensating current that has a magnitude the same as that of the dark current of the photodetector diode PD1.

In response to detected light, a certain quantity of current proportional to capacitance is stored in the photodetector diode PD1, the drive transistor M2 outputs the voltage of the photodetector diode PD1 by amplifying with an electric signal of a predetermined range (output voltage 0), and as the select transistor M3 is turned on, the output voltage from the drive transistor M2 is outputted according to the addressing order of a pixel array.

According to this embodiment of the invention as set forth above, the current mirror realized by the dark pixel 20 provides a compensating current corresponding to a dark current constantly to the photodetector diode PD1 to prevent rapid saturation of the pixel by the dark current, thereby improving the dynamic range of the pixel. In particular, the dark photodiode PD2 generates the dark current by varying its magnitude at the same ratio as the photodetector diode PD1, thereby to perfectly compensate the photodetector diode PD1 for the dark current with the magnitude varying according to temperature.

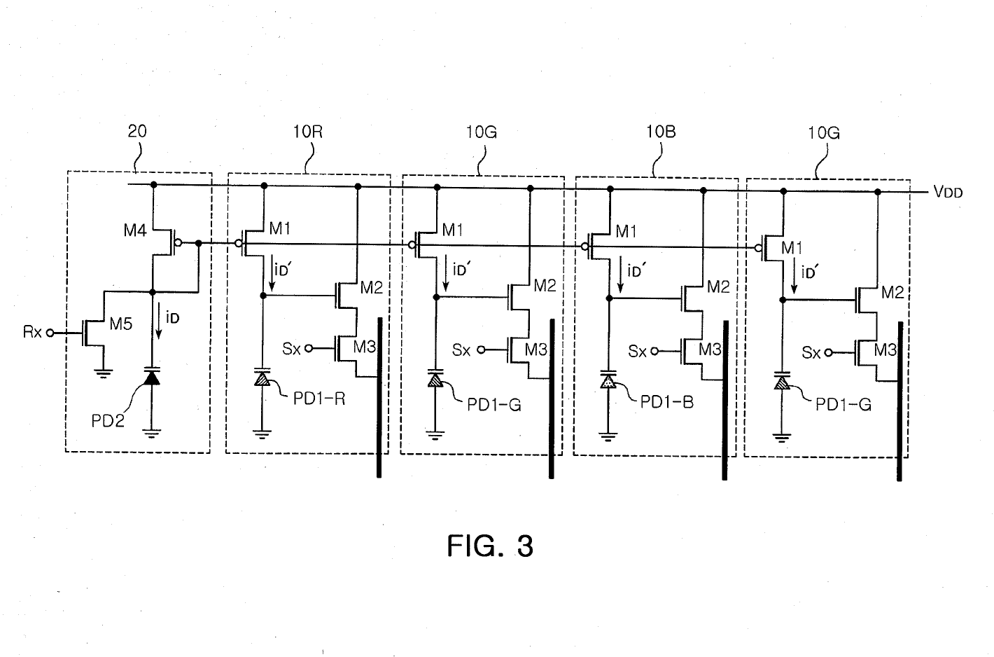

FIG. 3 is a circuit diagram illustrating a CMS image sensor according to another embodiment of the invention.

As shown in FIG. 3, the CMOS image sensor of this embodiment may include a pixel group in which a number of photodetector pixels 10R, 10G and 10B are connected to a single dark pixel 20. Then, a plurality of such pixel group are provided to realize an entire CMOS image sensor.

In the CMOS image sensor shown in FIG. 3, each of the photodetector pixels 10R includes a photodiode PD-R having a red filter, each of the photodetector pixels 10G includes a photodiode PD-G having a green filter, and each of the photodetector pixels 10B includes a photodiode PD-B having a blue filter. In this way, the photodetector pixels 10R, 10G and 10B can detect three primary lights. Regarding responsivity to each color light, the photodiode pixels include red-light photodiodes, blue-light photodiodes and green-light photodiodes in the ratio of 1:1:2.

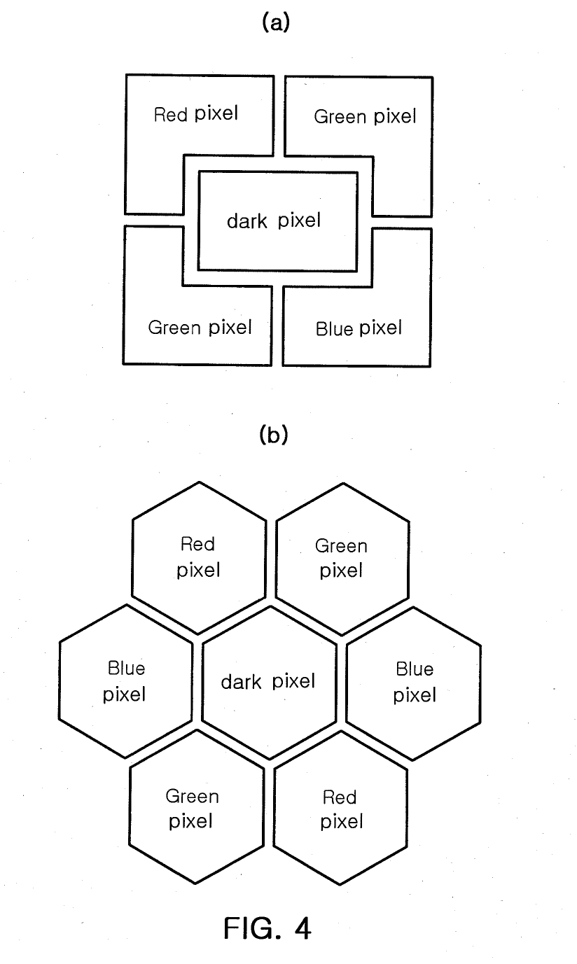

Neither the number of photodetector pixels connected to a single dark pixel nor the position of the dark pixel are not restricted. However, since response conditions may be varied according to the position of the CMOS image sensor, it is preferable that a suitable number of photodetector pixels are arranged in around a single dark pixel. FIG. 4 shows some examples of such pixel arrangement structure.

FIG. 4 is a diagram illustrating pixel arrangements of a CMOS image according to different embodiments of the invention.

First, as shown in FIG. 4(a), L-shaped four photodetector pixels are arranged around a rectangular dark pixel disposed in the center. The photodetector pixels include one red-light photodiode pixel, one blue-light photodiode pixel and two green-light photodiodes. Alternatively, as shown in FIG. 4(b), regular hexagonal photodetector pixels may be arranged around a regular hexagonal dark pixel so that a pair of photodiode pixels for the same color are arranged at opposed sides of the dark pixel.

According to certain embodiments of the invention as described hereinbefore, the dark pixel having a dark photodiode shielded from light is connected to at least one photodetector pixel. The dark pixel provides a current with the magnitude the same as that of a dark current occurring in the dark photodiode to a photodiode of the photodetector pixel to compensate the photodetector diode from a dark current.

Especially, the magnitude of the compensating current can be adjusted according to temperature change, thereby perfectly compensating the dark current of the photodetector diode that is variable according to temperature change.

By compensating for the dark current, it is possible to delay the saturation rate of the CMOS image sensor and thus enhance the dynamic range thereof.

What is claimed is:

1. A Complementary Metal Oxide Semiconductor (CMOS) image sensor comprising:
at least one photodetector pixel including a first reset transistor with a drain connected to a supply voltage and a photodetector diode connected between a source of the first reset transistor and a ground; and
at least one dark pixel including a mirror transistor with a drain connected to the supply voltage and a gate and source connected to a gate of the first reset transistor and a dark photodiode shielded from external light, the dark photodiode connected between the source of the mirror diode and the ground,
whereby a current having a magnitude equal with that of a dark current flowing through the dark photodiode is provided to the photodetector diode.

2. The CMOS image sensor according to claim 1, wherein the dark pixel further includes a second reset transistor with a drain connected to the source of the mirror transistor and a source connected to the ground, the second reset transistor receiving a reset signal through the gate.

3. The CMOS image sensor according to claim 1, wherein each of the first reset transistor and the mirror transistor comprises a p-channel Metal Oxide Semiconductor Field Effect Transistor (MOSFET).

4. The CMOS image sensor according to claim 1, comprising a plurality of the photodetector pixel arranged around and connected to a single one of the dark pixel to form a pixel group.

5. The CMOS image sensor according to claim 3, wherein the pixel group comprises the photodetector pixels include a red-light photodetector pixel, a blue-light photodetector pixel and green light photodetector pixels at a ratio of 1:1:2.
